(19) United States
(12) Patent Application Publication
(10) Pub. No.: US 2011/0233049 A1
(43) Pub. Date: Sep. 29, 2011

(54) SPUTTERING SYSTEM

(75) Inventors: Georg Henninger, Aachen (DE); Berno Hunsche, Langerwehe (DE); Konrad Sell, Aachen (DE); Manfred Ruske, Kerpen (DE); Thomas Diederich, Stolberg (DE)

(73) Assignee: KONINKLIJKE PHILIPS ELECTRONICS N.V., EINDHOVEN (NL)

(21) Appl. No.: 12/674,182

(22) PCT Filed: Aug. 21, 2008
(86) PCT No.: PCT/IB2008/053354

§ 371 Date: Feb. 19, 2010

(30) Foreign Application Priority Data
Aug. 30, 2007 (EP) 07115308.4

(51) Int. Cl. C23C 14/35

(52) U.S. Cl. 204/192.12; 204/298.16

(57) ABSTRACT

The invention relates to a device (10) for sputtering at least one selected materialonto a substrate (5) and bringing about a reaction of this material, comprising a vacuum chamber (11), in which a substrate holder (12) is arranged, at least one magnetron sputtering mechanism (15), which is arranged in a workstation close to the substrate holder (12) and which has a target of the selected material which is suitable for producing a first plasma for sputtering at least one material onto the substrate (5), as well as a secondary plasma mechanism (16) for producing a secondary plasma, which is arranged in the workstation close to the magnetron sputtering mechanism (15) and close to the substrate holder (12), the sputtering mechanism (15) and the secondary plasma mechanism (16) forming a sputtering zone and an activation zone. At least two electromagnets (1, 3) and/or radiallymagnetized toric magnets as well as at least one magnetic multipole (2), which is formed from a plurality of permanent magnets, are arranged to produce magnetic fields to include the secondary plasma. The invention also relates to a method for coating a substrate, in which firstly material is deposited on a substrate by means of a sputtering process and the deposited material then reacts in a plasma, which contains the necessary reactive species, to form a compound, wherein the plasma density and the degree of ionization of the plasma are increased with the aid of magnetic fields, which are produced by at least two electromagnets (1, 3) and/or radially magnetized toric magnets as well as at least one magnetic multipole (2), which is formed from a plurality of permanent magnets.

### FIELD OF THE INVENTION

The invention relates to a device for sputtering at least one selected material onto a substrate and bringing about a reaction of this material, comprising a vacuum chamber, in which a substrate holder is arranged, at least one magnetron sputtering mechanism, which is arranged in a workstation close to the substrate holder and which has a target of the selected material which is suitable for producing a first plasma for sputtering at least one material onto the substrate, as well as a secondary plasma mechanism for producing a secondary plasma, which is arranged in the workstation close to the magnetron sputtering mechanism and close to the substrate holder, the sputtering mechanism and the secondary plasma mechanism forming a sputtering zone and an activation zone. The invention also relates to a method for coating a substrate, in which firstly material is deposited on a substrate by means of a sputtering process and the deposited material then reacts in plasma, which contains the necessary reactive species, to form a compound.

### BACKGROUND OF THE INVENTION

The use of reactive magnetron sputtering is known for applying thin films of metal compounds. A reactive sputtering is carried out in this connection such that the substrate is fastened over the metallic target and a compounding of the applied metal film takes place at the same time and at the same location as the depositing of the metal atoms. To achieve stoichiometric films with acceptable depositing rates, careful balancing of the conditions is necessary, so the film is completely composed or compounded on the substrate, but the sputtering target surface is not “poisoned” by excessive reaction, as a state such as this leads to lower sputtering rates and often to arc formation on the target surface.

Furthermore, it is known to guide the substrate, on which the metal compound is to be deposited, alternatingly over the sputtering target and through a reactive atmosphere. In this manner, the depositing of the metal atoms is in each case partially separated, with respect to time and space, from the compounding of the film. It is furthermore known that the depositing of an oxide layer can be improved in that oxygen in the compounding zone is activated by a plasma, as excited oxygen species react more easily with the metal layer.

The drawback in the aforementioned prior art is the necessity for physical and atmospheric separation of the reaction and deposition zone. This separation, for example, limits the number of targets and reaction zones which can be arranged in a specific vacuum chamber, so the total quantity of film application is limited.

To avoid this drawback, it is proposed in EP 0 516 436 B1 to bring the sputtering and activation zone together atmospherically and physically, in that all the separation sheets are removed or no differential pumping is used and the plasmas of these two zones are thus effectively mixed to form a single continuous plasma which is used both for sputtering material from the target and for the reaction thereof on the substrate. A magnetron sputtering device is disclosed, in which a sputtering mechanism and a secondary plasma mechanism are arranged, which in each case form sputtering and activation zones, which are atmospherically and physically adjacent, and are suitable for improving the plasma of the sputtering mechanism to bring about a reaction of the ions of the reactive gas with the sputtering material with a comparatively low ambient part pressure of the reactive gas. In this case, a substrate holder is provided, which guides the substrates past the associated selected workstations.

It was possible to significantly improve the coating process by means of sputtering and subsequent bringing about of a reaction, for example an oxidation, by means of the device disclosed in EP 0 516 436 B1. The process time is substantially limited by the reaction to be brought about, for example the oxidation of the deposited material.

### SUMMARY OF THE INVENTION

It is an object of the present invention to improve the previously known device in such a way that the reaction rate in the activation zone is increased so that the process times can be reduced. According to the invention, this object is achieved in that at least two electromagnets and/or radially magnetized toric magnets as well as at least one magnetic multipole, which is formed from a plurality of permanent magnets, are arranged to produce magnetic fields to include the secondary plasma.

A device is provided by the invention, in which the reaction rate in the activation zone is increased, so the process times can be reduced.

In a development of the invention, the substrate holder is a drum and at least one electromagnet and/or a radially magnetized tonic magnet is arranged inside the drum. As a result, the plasma density close to or on the substrate is increased. The thus increased concentration of reactive species such as ions and radicals leads to an increase in the reaction rate.

In a configuration of the invention, all the magnets arranged to produce the magnetic field are arranged outside the vacuum chamber. This facilitates the mechanical arrangement. Furthermore, the outlay for cooling the magnetic components is reduced.

In an alternative configuration of the invention, all the magnets arranged to produce the magnetic field are arranged inside the vacuum chamber. This reduces the installation size of the device.

At least one electromagnet is preferably connected to an alternating voltage source to produce a magnetic alternating field. Advantageously, at least one of the electromagnets producing a magnetic alternating field is arranged in front of the substrate holder. As a result, the ion flow inside the plasma is further concentrated on the substrate.

In a configuration of the invention, at least one electromagnet is connected to a direct voltage source to produce a constant magnetic field. As a result, a further modification of the magnetic field produced to include the secondary plasma is made possible.

At least one electromagnet is preferably operated in such a way that a superimposed constant and alternating field is produced, so that a change in the magnetic field strength is implemented without a polarity reversal of the magnetic field. As a result, an effective compression of the plasma and a release of the ions necessary for the reaction on the substrate is brought about.

In a further configuration of the invention, the secondary plasma mechanism is a microwave generator. Generators of this type have been successful in producing the required plasma.

The microwave generator is preferably set up to produce a pulsed microwave. As a result, with the same output, higher plasma densities are achieved than in continuous microwave operation.

The arranged magnets advantageously generate magnetic fields with a maximum magnetic flux density, which is above the necessary magnetic flux density depending on the microwave frequency that is necessary to produce electron cyclotron resonance (ECR) in microwave plasma. This resonance state brings about an improved plasma excitation and a significant increase in the plasma density and the electron temperature. The magnetic flux density B_{ECR} necessary for the resonance case is calculated according to: B_{ECR}=f_{μW} mₑ/e₀, wherein f_{μW} is the microwave frequency, mₑ is the mass of an electron and e₀ is the elementary charge. A magnetic flux density of 875 Gauss is produced from this for a typical microwave frequency of 2.45 GHz, so that ECR conditions are present.

In a further configuration of the invention, a potential is applied at the substrate holder, which is different from the potential of the vacuum chamber. As a result, a further acceleration of the plasma ions is brought about in the direction of the substrate.

The invention is further based on an object of providing a method for coating a substrate, in which the reaction rate of the reaction to be brought about of the metal deposited on the substrate, for example an oxidation, is increased. According to the invention, this object is achieved in that the density and the degree of ionization of the plasma is increased with the aid of magnetic fields, which are produced by at least two electromagnets and/or radially magnetized tonic magnets as well as at least one magnetic multipole, which is formed from a plurality of permanent magnets.

A method for coating a substrate is provided by the invention, in which the reaction rate of the reaction to be brought about of the deposited metal on the substrate is increased.

Other developments and configurations of the invention are given in the remaining sub-claims. One embodiment of the invention is shown in the drawings and will be described in detail below.

### BRIEF DESCRIPTION OF THE DRAWINGS

In the drawings:

FIG. 1 shows the schematic simplified view of the cross-section of a drum-like vacuum coating device;

FIG. 2 shows a detail of the magnetron sputtering device in the region of the activation zone;

FIG. 3 shows the section 1-1 through the multipole magnets in FIG. 2;

FIG. 4 shows the schematic view of the magnetic field lines and the plasma inclusion in the arrangement according to FIG. 2 and

FIG. 5 shows the plan view of a detail of a magnetron sputtering device in a further embodiment in the region of the activation zone.

### DETAILED DESCRIPTION OF EMBODIMENTS

The sputtering device selected as an embodiment is a development of the sputtering system as described in EP 0 516 436 B1, reference being made here to the disclosure of this document.

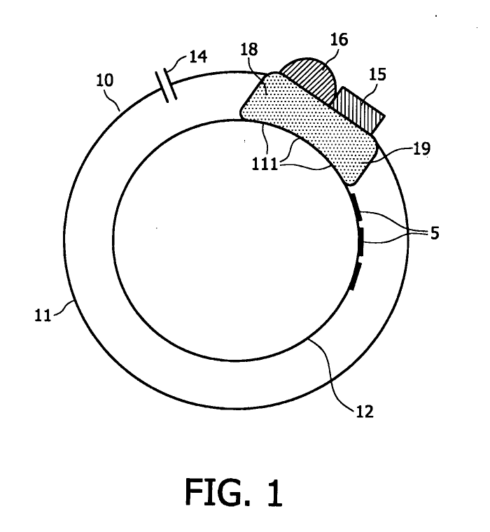

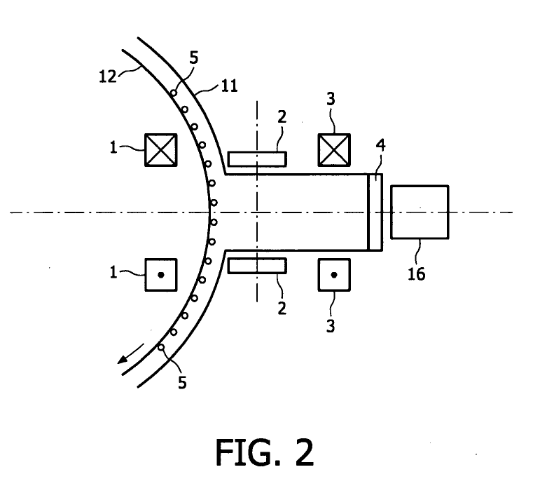

With reference to FIG. 1, a sputtering system 10 has a housing 11, the periphery of which forms a vacuum chamber. The housing 11 may itself be connected to a vacuum system, not shown. A magnetron sputtering device 15 is arranged on the periphery of the vacuum housing of the housing 11, which is also designated hereinafter as the chamber 11, closely adjacent to the plasma production device 16. In the embodiment, the plasma production device 16 is a microwave generator.

During operation, an inert sputtering gas, such as, for example, argon, is introduced into the chamber 11 through an inlet 14. In addition, a reaction gas, such as, for example, oxygen, is introduced through the inlet 14. As the substrates, which are arranged on the drum 12, are rotated into the region 19 of the larger plasma 111, a metal film sputtered from the target 15 is deposited. The reaction of this film with the reaction gas begins directly when the film is deposited in the region 19 below the target 15. If the substrate 5 is guided into the region 18 of the plasma under the microwave generator 16, this reaction is continued and the conversion of the film into a dielectric with the desired stoichiometry is brought to an end. In order to achieve a dielectric film of a desired thickness, this sequence can be repeated by rotating the drum 12. By means of the arrangement of further sputtering target plasma production devices, multi-layer films of various materials can be applied to the substrates 5.

To increase the reaction rate—in the case of oxygen as the reaction gas, the oxidation rate—arranged in the activation zone in the region 18 is a magnetic field arrangement, consisting of two electromagnets 1, 3 and a magnetic multipole 2, which is constructed from a plurality of permanent magnets. The magnetic fields are used to include the electrons. The microwave generator 16 operates at 2.45 gigahertz and the magnetic fields initiated by the magnetic field arrangement have a maximum magnetic flux density of more than 875 Gauss, so a resonance state (ECR state) is brought about. A reciprocal action of the magnetic field with the ions of the plasma can be ignored as the ions in the ECR plasma have a thermal behaviour.

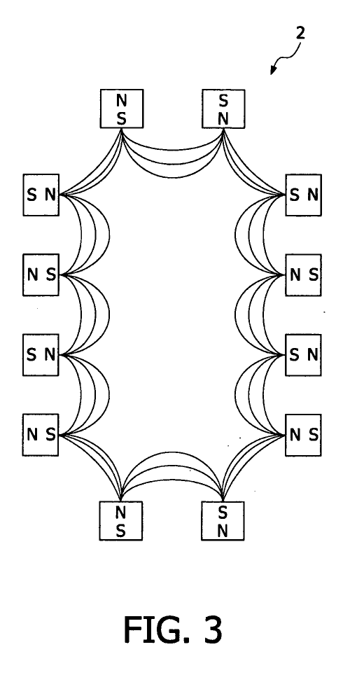

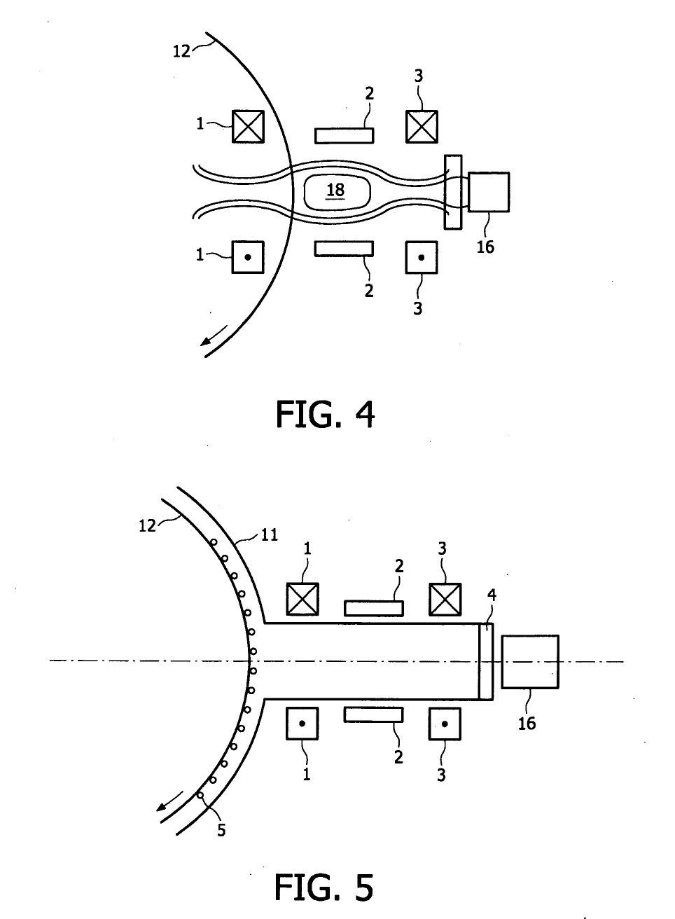

In the magnetic field arrangement according to FIG. 3, an electromagnet is arranged inside the drum 12. The multipole magnet 2 and a second electromagnet 3 are arranged with respect to the electromagnet 1 outside the vacuum chamber on the housing 11. The substrates 5 fastened to the drum 12 are moved on the rotating drum 12 by the magnetic field configuration. With the aid of the two electromagnets, a magnetic double mirror is constructed, which is used for the axial inclusion of the electrons. Instead of magnetic coils, radially magnetized toric magnets can also be used here. Owing to the curvature of the magnetic mirror field, a drift of the electrons radially outwardly takes place. This drift movement leads to plasma instabilities. For stabilization, a radial magnetic inclusion of the electrons is implemented with the aid of the multipole magnet 2, which is arranged between the two electromagnets 1, 3.

The presence of ECR conditions leads to an increase in the absorption of microwave energy in the plasma by means of the resonant excitation of the electrons when passing through the ECR surfaces. As a result of the resonant electron excitation, increased ionization processes occur and therefore an increase in the charge carrier density (plasma excitation). The ions are included by the plasma potential distribution forming (electrostatic inclusion). The cause of the plasma potential distribution is large gradients in the electron density and electron temperature. These gradients are produced from the ECR conditions occurring locally to a limited extent (location of the maximum electron excitation by the microwaves).

To protect the microwave window 4 arranged on the housing, this microwave window 4 should be positioned in such a way that no ECR conditions are present on the vacuum side directly in front of the microwave window 4. An excessive thermal stressing of the microwave window 4 is thus prevented. The ECR surface of the electromagnet 3 remote from the drum should preferably be arranged on the atmosphere side. Furthermore, the microwave window 4 is protected by keeping away the plasma via the magnetic plasma inclusion.

In order to bring about a targeted ion flow onto the substrates, applied at the drum 12, on which the substrates 5 are fastened, is a potential, which is different from that of the vacuum chamber 11. For this purpose, a negative bias is applied at the drum 12. To prevent an ion flow onto the substrates 5, a positive bias should be applied here if a reaction with neutral particles is preferred.

By means of the above-described magnetic field arrangement, a plasma inclusion is brought about, which leads to an increase in the charge carrier density and the electron temperature. The substrates 5, which are located on the drum 12, are guided by rotation of the drum 12 through the included plasma and therefore subjected to improved oxidation. In addition, the loss of charge carriers, in other words recombination and migration of the ions and electrons in regions of the receivers, in which they do not contribute to the maintenance of a plasma, and no effective oxidization of the substrates 5 can occur, is minimized.

1. A device for sputtering at least one selected material onto a substrate and bringing about a reaction of this material, the device comprising a vacuum chamber, in which a substrate holder is arranged, at least one magnetron sputtering mechanism, which is arranged in a workstation close to the substrate holder and which has a target of the selected material which is suitable for producing a first plasma for sputtering at least one material onto the substrate, as well as a secondary plasma mechanism for producing a secondary plasma, which is arranged in the workstation close to the magnetron sputtering mechanism (15) and close to the substrate holder, the sputtering mechanism and the secondary plasma mechanism forming a sputtering zone and an activation zone, wherein at least two electromagnets and/or radially magnetized toric magnets as well as at least one magnetic multipole, which is formed from a plurality of permanent magnets, are arranged to produce magnetic fields to include the secondary plasma.

2. A device as claimed in claim 1, wherein the substrate holder is a drum and in that at least one electromagnet and/or one radially magnetized toric magnet is arranged inside the drum.

3. A device as claimed in claim 1, wherein all the magnets arranged to produce the magnetic fields are arranged outside the vacuum chamber.

4. A device as claimed in claim 1, wherein all the magnets arranged to produce the magnetic fields are arranged inside the vacuum chamber.

5. A device as claimed in claim 1, wherein at least one electromagnet for producing a magnetic alternating field is connected to an alternating voltage source.

6. A device as claimed in claim 1, wherein at least one electromagnet for producing a constant magnetic field is connected to a direct voltage source.

7. A device as claimed in claim 1, wherein at least one electromagnet is operated in such a way that a superimposed constant and alternating field is produced.

8. A device as claimed in claim 1, wherein the secondary plasma mechanism is a microwave generator.

9. A device as claimed in claim 8, wherein the microwave generator is set up to produce a pulsed microwave.

10. A device as claimed in claim 8, wherein the maximum magnetic flux density of the magnetic fields produced by the arranged magnets corresponds at least to the necessary magnetic flux density matched to the microwave frequency used to produce electron cyclotron resonance (ECR).

11. A device as claimed in claim 1, wherein a potential is applied at the substrate holder, which is different from the potential of the vacuum chamber.

12. A device as claimed in claim 1 wherein the secondary plasma brings about a reaction to convert the selected material into an oxide, nitride, carbide, hydride, sulfide, oxynitride or mixtures thereof.

13. A device as claimed in claim 1 wherein the secondary plasma is an oxygen-rich plasma and in that the reaction brought about is an oxidation.

14. A method for coating a substrate, in which firstly material is deposited on a substrate by means of a sputtering process and the deposited material then reacts in a plasma, which contains the necessary reactive species, to form a compound, wherein the plasma density and the degree of ionization of the plasma are increased with the aid of magnetic fields, which are produced by at least two electromagnets and/or radially magnetized toric magnets as well as at least one magnetic multipole, which is formed from a plurality of permanent magnets.

15. A method as claimed in claim 14, wherein the maximum magnetic flux density of the magnetic fields produced by the arranged magnets corresponds at least to the necessary magnetic flux density matched to the microwave frequency used, to produce electron cyclotron resonance (ECR).
